(19) United States
(12) Patent Application Publication
(10) Pub. No.: US 2015/0271470 A1
(43) Pub. Date: Sep. 24, 2015

(54) METHOD OF USING A LIGHT-FIELD CAMERA TO GENERATE A FULL DEPTH-OF-FIELD IMAGE, AND LIGHT FIELD CAMERA IMPLEMENTING THE METHOD

(71) Applicants: NATIONAL TAIWAN UNIVERSITY, TAIPEI CITY 10617 (TW); LITE-ON TECHNOLOGY CORP., TAIPEI 11492 (TW)

(72) Inventors: JIUN-HUEI PROTY WU, TAIPEI CITY 10617 (TW); ZONG-SIAN LI, TAIPEI 11492 (TW)

(21) Appl. No.: 14/658,538

(22) Filed: Mar. 16, 2015

(30) Foreign Application Priority Data
Mar. 21, 2014 (TW) 103110698

(51) Int. Cl. H04N 13/02; H04N 13/00

(52) U.S. Cl. CPC H04N 13/0217; H04N 13/0228; H04N 13/004

(57) ABSTRACT

A method is provided to generate a full depth-of-field image using a light-field camera that includes a main lens, a micro-lens array, a light sensing component, and an image processing unit. The micro-lens array forms a plurality of micro-images at different positions of the light sensing component. The image processing unit obtains, for each of the micro-images, an image pixel value according to one of the pixels that is disposed at a specific position of the micro-image, and arranges the image pixel values obtained for the micro-images according to positions of the micro-images on the light sensing component to generate the full depth-of-field image.

### CROSS-REFERENCE TO RELATED APPLICATION

This application claims priority to Taiwanese Application No. 103110698, filed on Mar. 21, 2014.

### BACKGROUND OF THE INVENTION

1. Field of the Invention

The invention relates to a method to generate a full depth-of-field image, and more particularly to a method of using a light-field camera to generate a full depth-of-field image.

2. Description of the Related Art

A full depth-of-field image is generated in a conventional manner by combining multiple images that are captured under different photography conditions, which involve various parameters such as aperture, shutter, focal length, etc. Different images of the same scene are captured by changing one or more parameters, and a clear full depth-of-field image is obtained by using an image definition evaluation method to combine these images.

During the abovementioned capturing process, the photographer has to determine, based on experience, how many images of different photography conditions are required according to distribution of objects in the scene. After capturing, post processing, such as using computer software for image synthesis, is required to obtain the full depth-of-field image. Overall, such a conventional method takes up a significant amount of time to obtain the full depth-of-field image, and the complex process is inconvenient. Another conventional method is to sharpen blurry parts of an image using deconvolution operation according to blurry levels thereof. However, such a method requires a long time for large amounts of calculations.

### SUMMARY OF THE INVENTION

Therefore, an object of the present invention is to provide a method of using a light-field camera to generate a full depth-of-field image. The method is able to save overall time required for capturing and effectively reduce calculations for generating a full depth-of-field image since post processing is not necessary.

According to one aspect of the present invention, a method of using a light-field camera to generate a full depth-of-field image is provided. The light-field camera includes a main lens for collecting light field information from a scene, a micro-lens array that includes a plurality of microlenses, a light sensing component, and an image processing unit. The method comprises:

(a) forming, using the micro-lens array, a plurality of micro-images at different positions of the light sensing component according to the light field information collected by the main lens, each of the micro-images including a plurality of pixels;

(b) for each of the micro-images, obtaining, by the image processing unit, an image pixel value according to one of the pixels that is disposed at a specific position of the micro-image, wherein the specific positions of the micro-images correspond to each other; and

(c) arranging, by the image processing unit, the image pixel values obtained for the micro-images according to positions of the micro-images on the light sensing component to generate the full depth-of-field image.

Another object of the present invention is to provide a light-field camera that implements the method of the present invention.

According to another aspect of the present invention, a light-field camera comprises a main lens, a micro-lens array including a plurality of microlenses, and a light sensing component arranged in order from an object side to an image side, and an image processing unit.

The main lens is configured to collect light field information from a scene.

The micro-lens array is configured to form a plurality of micro-images at different positions of the light sensing component according to the light field information collected by the main lens. Each of the micro-images includes a plurality of pixels.

The image processing unit is configured to:
for each of the micro-images, obtain an image pixel value according to one of the pixels that is disposed at a specific position of the micro-image, wherein the specific positions of the micro-images correspond to each other; and
arrange the image pixel values obtained for the micro-images according to positions of the micro-images on the light sensing component to generate the full depth-of-field image.

### BRIEF DESCRIPTION OF THE DRAWINGS

Other features and advantages of the present invention will become apparent in the following detailed description of an embodiment with reference to the accompanying drawings, of which:

FIG. 1 is a schematic diagram illustrating an embodiment of a light-field camera according to the present invention;

FIG. 2 is a schematic diagram illustrating relationships of a plurality of micro-images formed on a light sensing component of the embodiment and a resulting full depth-of-field image;

FIG. 3 is a schematic diagram illustrating an example in which each of the micro-images has an even number of pixel rows and an even number of pixel columns;

FIG. 4 is a schematic diagram illustrating an example in which each of the micro-images has an odd number of pixel rows and an even number of pixel columns;

FIG. 5 is a schematic diagram illustrating an example in which each of the micro-images has an odd number of pixel rows and an odd number of pixel columns; and

FIG. 6 is a flow chart illustrating steps of an embodiment of a method of using a light-field camera to generate a full depth-of-field image according to the present invention.

### DETAILED DESCRIPTION OF THE EMBODIMENT

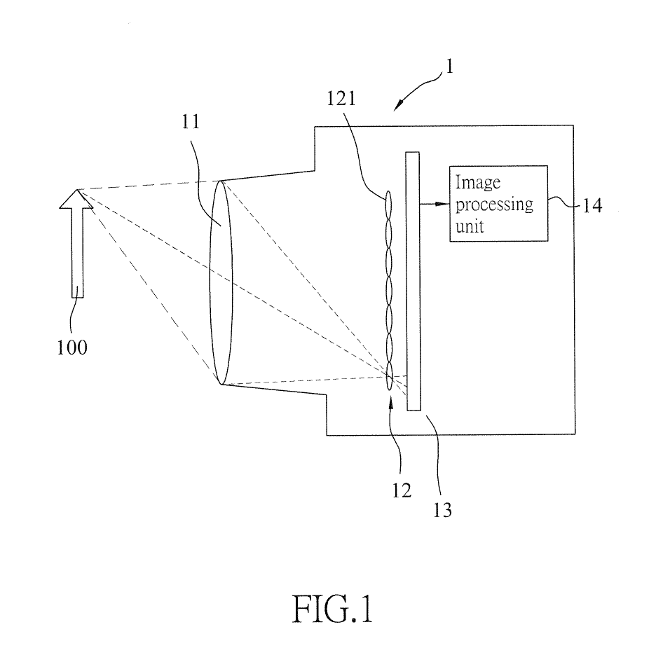

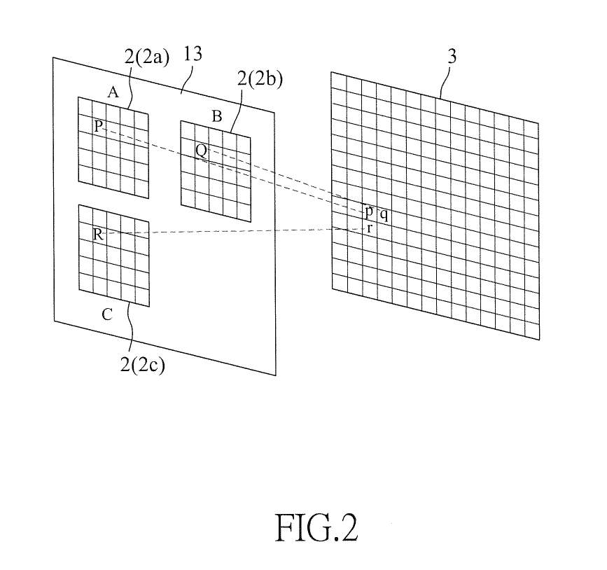

Referring to FIGS. 1 and 2, the embodiment of the light-field camera 1 adapted to generate a full depth-of-field image according to this invention is shown to include a main lens 11, a micro-lens array 12 and a light sensing component 13 arranged in the given order from an object side to an image side, and an image processing unit 14.

The micro-lens array 12 includes a plurality of microlenses. In this embodiment, the microlenses 121 are arranged in a rectangular array.

The main lens 11 collects light field information from a scene 100. The microlenses of the micro-lens array 12 form a plurality of micro-images 2 at different positions of the light sensing component 13 according to the light field information collected by the main lens 11. Each of the micro-images 2 includes a plurality of pixels and corresponds to a respective one of the microlenses. In this embodiment, the micro-images 2 have the same number of pixels.

For each of the micro-images 2, the image processing unit 14 obtains an image pixel value according to one of the pixels that is disposed at a specific position of the micro-image, which is called an image pixel hereinafter. Note that the specific position is a location of the image pixel on the micro-image 2 and corresponds to a specific viewing angle, and the specific positions of the micro-images 2 correspond to each other (i.e., the image pixel of one micro-image 2 is identical in relative position thereof within the micro-image 2 with the image pixels of the other micro-images 2). In this embodiment, the image processing unit 14 may obtain a pixel value of the image pixel to serve as the image pixel value of the micro-image 2. In another embodiment, the image processing unit 14 may obtain a weighted average of pixel values of the image pixel and pixels disposed in a vicinity of the image pixel, and the weighted average serves as the image pixel value of the micro-image 2. Note that the pixels disposed in the vicinity of the image pixel are called neighboring pixels hereinafter. Then, the image processing unit 14 arranges the image pixel values obtained for the micro-images 2 according to positions of the micro-images 2 on the light sensing component 13 to generate a full depth-of-field image 3. Through setting different specific positions, the full depth-of-field image 3 thus obtained may correspond to different viewing angles. A number of the viewing angles to which the full depth-of-field image 3 may correspond is equal to a number of the pixels of each micro-image 2.

The imaging result of the aforementioned method is characterized in full depth-of-field by using a pixel value of a single pixel or a weighted average of the single pixel and its neighboring pixels to immediately obtain the full depth-of-field image 3, and time of algorithm calculation for refocusing is hardly or not required. In more detail, raw data of the light-field camera 1 is used to select a pixel value of a single pixel at the specific position or to obtain a weighted average of the single pixel and its neighboring pixels for performing image synthesis, so as to quickly (e.g., about 0.5 second or within 1 second) obtain the full depth-of-field image 3 with a certain high resolution using only minimal calculations. The full depth-of-field image 3 thus obtained then may be used for a variety of applications. As an example, the full depth-of-field image 3 may be used to calculate a depth map, and any kind of light-field cameras may employ such a software technique in order to obtain a full depth-of-field image within a short period of time.

Hereinafter, it is exemplified that the image processing unit 14 obtains, for each of the micro-images 2, a pixel value of the single image pixel, which is disposed at the specific position identical in relative position thereof within the micro-image 2 with the specific positions of the other micro-images 2, to serve as the image pixel value. Referring to FIG. 2, each micro-image 2 has 25 pixels, that is, 25 viewing angles may be selected for the full depth-of-field image 3. The image processing unit 14 selects pixels that are disposed at corresponding positions of the micro-images 2 to form the full depth-of-field image 3 corresponding to the selected viewing angle. Referring to FIG. 2, pixels P, Q, R are respectively disposed on corresponding specific positions of the micro-images 2a, 2b and 2c (i.e., the position corresponding to both of the second row and the second column for each of the micro-images 2a, 2b and 2c). Herein, it is assumed that the specific position of each of the micro-images 2a, 2b and 2c corresponds to a k^{th} viewing angle, and the micro-images 2a, 2b and 2c are respectively disposed at adjacent A, B and C positions of the light sensing component 13. Locations of pixels p, q and r in the full depth-of-field image 3 that corresponds to the k^{th} viewing angle respectively correspond to the positions A, B and C of the micro-images 2a, 2b and 2c on the light sensing component 13. That is, since the micro-image 2a is at the left side of the micro-image 2b, the pixel p is disposed at the left side of the pixel q in the full depth-of-field image 3, and since the micro-image 2a is at the upper side of the micro-image 2c, the pixel p is disposed at the upper side of the pixel r in the full depth-of-field image 3. Note that only a part of the micro-images 2 are shown in FIG. 2 for the sake of clarity.

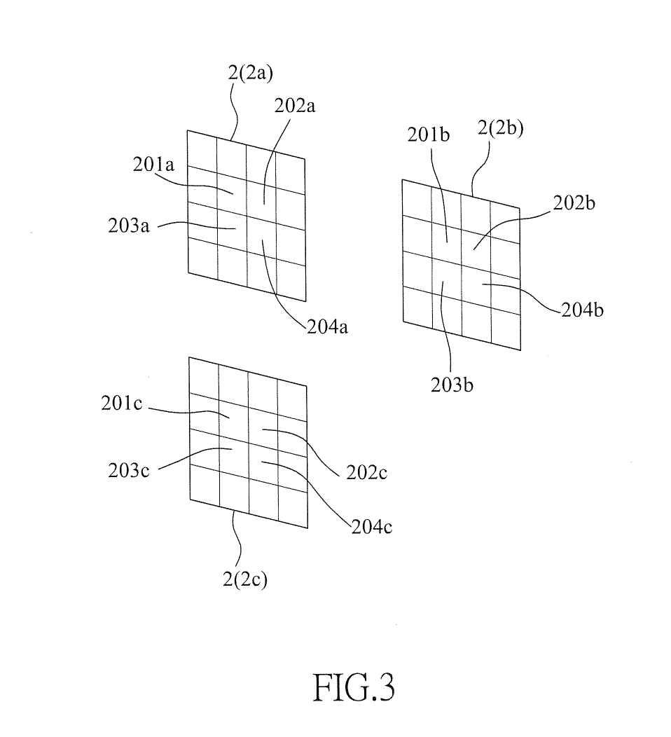

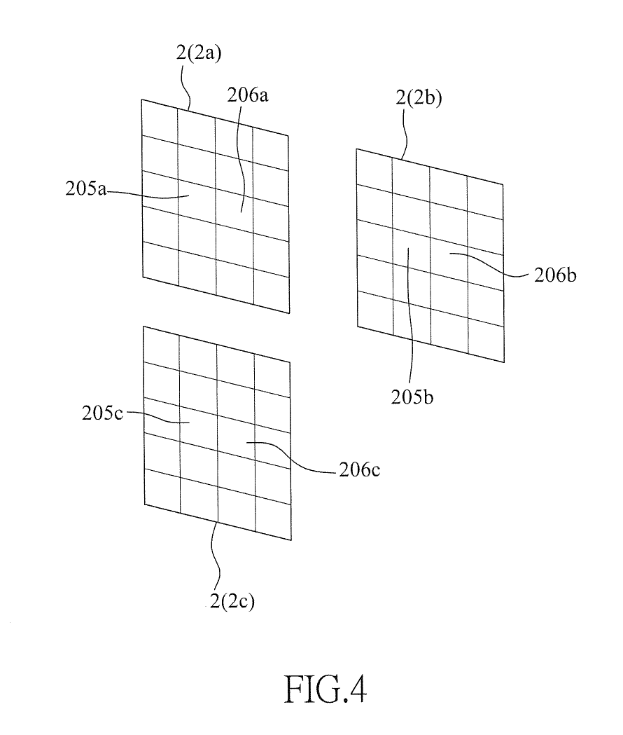

When each of the micro-images 2 has an even number of pixels, namely, both of numbers of pixel columns and pixel rows are even (see FIG. 3), or only one of the numbers of pixel columns and pixel rows is even (see FIG. 4), the image pixel of the micro-image 2, which is disposed at the specific position of the micro-image 2, may be any one of the pixels that is adjacent to a center of the micro-image 2.

In one example, referring to FIG. 3 in which each of the micro-images 2a, 2b and 2c has an even number of pixel columns and an even number of pixel rows, any one of the four pixels that are respectively disposed at the upper-left side, the upper-right side, the lower-left side and the lower-right side of the center of the micro-image 2 may be a candidate of the image pixel. When the upper-left one is selected to be the image pixel, the image pixels of the micro-images 2a, 2b and 2c are pixels 201a, 201b and 201c, respectively. When the upper-right one is selected to be the image pixel, the image pixels of the micro-images 2a, 2b and 2c are pixels 202a, 202b and 202c, respectively. When the lower-left one is selected to be the image pixel, the image pixels of the micro-images 2a, 2b and 2c are pixels 203a, 203b and 203c, respectively. When the lower-right one is selected to be the image pixel, the image pixels of the micro-images 2a, 2b and 2c are pixels 204a, 204b and 204c, respectively.

When one of the numbers of the pixel columns and the pixel rows is odd and the other one is even, any one of the two pixels that are adjacent to the center of the micro-image 2a, 2b and 2c may be a candidate of the image pixel. In one example, referring to FIG. 4 in which each of the micro-images 2a, 2b and 2c has an even number of pixel columns and an odd number of pixel rows, the pixels respectively disposed at the left and right sides that are adjacent to a center of the micro-image 2 may be a candidate of the image pixel. When the left one is selected to be the image pixel, the image pixels of the micro-images 2a, 2b and 2c are pixels 205a, 205b and 205c, respectively. When the right one is selected to be the image pixel, the image pixels of the micro-images 2a, 2b and 2c are pixels 206a, 206b and 206c, respectively.

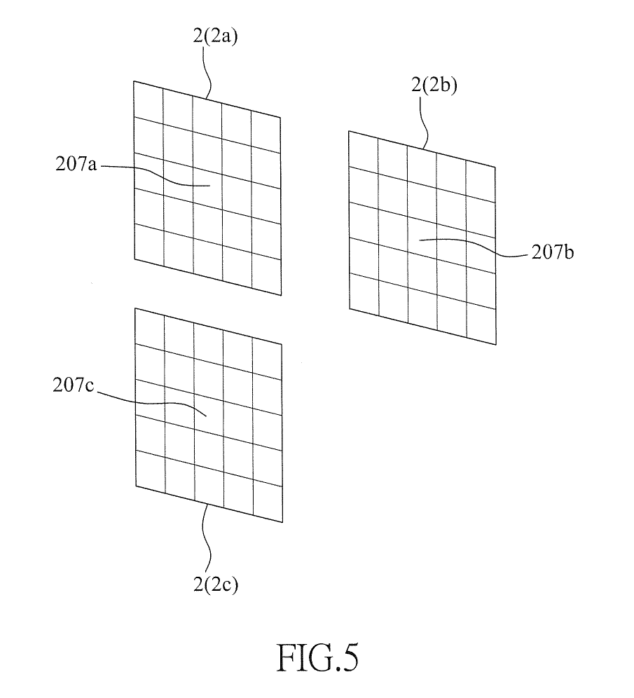

In one example, referring to FIG. 5 in which each of the micro-images 2a, 2b and 2c has an odd number of pixel columns and an odd number of pixel rows, the central pixel of the micro-image 2, i.e., the pixels 207a, 207b and 207c, may be selected to be the image pixel.

Note that in the aforementioned examples, the image pixel is selected from the pixels at the middle part (i.e., a position at or adjacent to a center/central pixel of the micro-image 2) of the micro-image 2 since the light emitted thereto passes through a central portion of the main lens 11, and has smaller optical aberration. However, the present invention should not be limited in this respect, and the image pixel may be selected from the pixels disposed on non-middle parts of the micro-image 2 in other embodiments.

In addition, the image processing unit 14 may be configured to perform interpolation on the full depth-of-field image 3 to increase resolution of the full depth-of-field image 3. As an example, assuming the micro-lens array 12 is an M×N array, the resolution of the original full depth-of-field image 3 should be M×N. After first interpolation, the resolution of the full depth-of-field image 3 may be increased to (2M−1)×(2N−1). Then, by duplication of the uppermost or lowermost row of pixels of the full depth-of-field image with the resolution of (2M−1)×(2N−1), the numbers of rows of the full depth-of-field image may be increased to 2N. Similarly, by duplication of the leftmost or rightmost column of pixels of the full depth-of-field image with the resolution of (2M−1)×2N, the number of columns of the full depth-of-field image 3 may be increased to 2M, so as to obtain the full depth-of-field image with the resolution of 2M×2N. Moreover, through a similar manner, the resolution of the full depth-of-field image may be further increased to 4M×4N, and the present invention should not be limited in this respect.

The full depth-of-field image 3 generated in such a manner would not have blurry issues, thereby achieving good effects after interpolation. For example, the increased resolution of the full depth-of-field image results in a sharp visual sense. In practice, the interpolation may be performed using, but not limited to, nearest-neighborhood interpolation, bilinear interpolation, bi-cubic interpolation, etc., which are well-known to those skilled in the art, and which will not be described in further detail herein for the sake of brevity.

Moreover, the image processing unit 14 may be further configured to sharpen the full depth-of-field image 3 (see FIG. 2) after the abovementioned interpolation process, so as to enhance edges and contours in the full depth-of-field image whose resolution was increased via the interpolation, thereby causing the image 3 to be clearer.

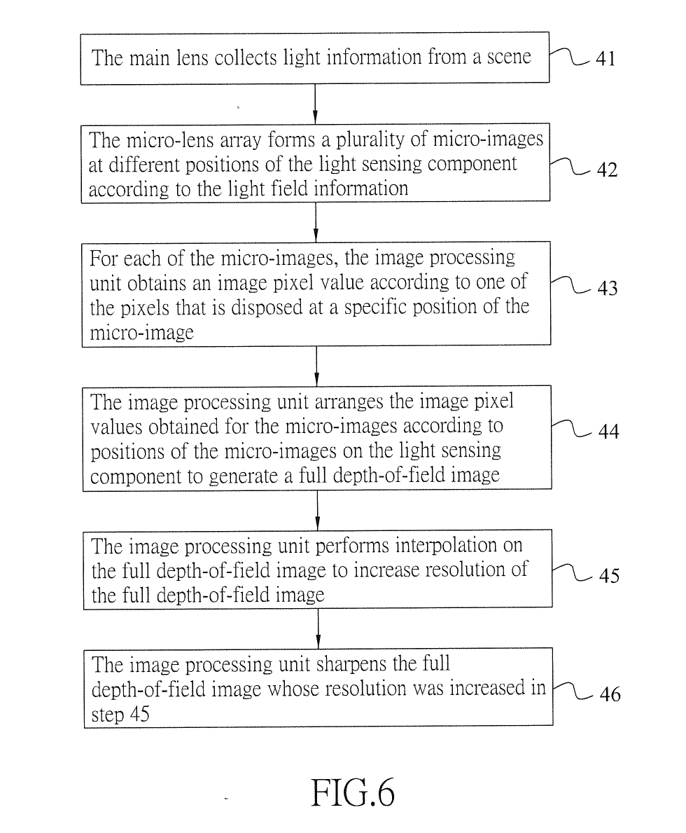

Referring to FIGS. 1, 2 and 6, the embodiment of the method of using the light-field camera 1 to generate a full depth-of-field image includes the following steps:

Step 41: The main lens 11 collects light information from a scene 100.

Step 42: The micro-lens array 12 forms a plurality of micro-images 2 at different positions of the light sensing component 13 according to the light field information collected by the main lens 11.

Step 43: For each of the micro-images 2, the image processing unit 14 obtains an image pixel value according to one of the pixels (i.e., the image pixel) that is disposed at a specific position of the micro-image 2. Note that the specific positions of the micro-images 2 correspond to each other (i.e., the image pixel of one micro-image 2 is identical in relative position thereof within the micro-image with the image pixels of the other micro-images 2), and correspond to a specific viewing angle. In one embodiment, when each of the micro-images 2 has an even number of pixels, the image pixel may be one of the pixels near the center of the micro-image 2. Referring to FIG. 3 as an example, the image pixels of the micro-images 2a to 2c may be respectively the pixels 201a to 201c, may be respectively the pixels 202a to 202c, may be respectively the pixels 203a to 203c, or may be respectively the pixels 204a to 204c. Referring to FIG. 4 as another example, the image pixels of the micro-images 2a to 2c may be respectively the pixels 205a to 205c, or may be respectively the pixels 206a to 206c.

When each of the micro-images 2 has an odd number of pixels, the image pixel may be the central pixel of the micro-image 2. Referring to FIG. 5 as a further example, the image pixels of the micro-images 2a to 2c may be respectively the pixels 207a to 207c.

Note that when the image processing unit 14 obtains a weighted average of pixel values of the image pixel and the neighboring pixels to serve as the image pixel value, the neighboring pixels may be the pixels adjacent to the image pixel at an upper side, a lower side, a left side and a right side of the image pixel, and a sum of weights of the image pixel and the neighboring pixels is equal to 1. However, the present invention should not be limited to the abovementioned example. Numbers of the neighboring pixels and the weights of the image pixel and the neighboring pixels may be adjusted as required.

Step 44: The image processing unit 14 arranges the image pixel values obtained for the micro-images 2 according to positions of the micro-images 2 on the light sensing component 13 to generate the full depth-of-field image 3.

Step 45: The image processing unit 14 performs interpolation on the full depth-of-field image 3 to increase resolution of the full depth-of-field image 3.

Step 46: The image processing unit 14 sharpens the full depth-of-field image 3 whose resolution was increased in step 45.

To sum up, the image processing unit 14 of the present invention may be used to obtain an image pixel value for each of the micro-images 2 according to a image pixel of the micro-image 2 (i.e., the pixel value of the single image pixel, or the weighted average of the image pixel and its neighboring pixels), which corresponds to a desired viewing angle, so as to generate a full depth-of-field image 3 corresponding to the desired viewing angle. As described hereinbefore complex calculations and multiple images that are captured with different focal lengths are not required during generation of the full depth-of-field image 3 through use of the disclosed embodiment of the light-field camera 1, so as to reduce processing time that is required for calculations and capturing in the prior art. Moreover, the techniques used in the disclosed embodiment of the light-field camera 1 may generate multiple full depth-of-field images 3 with different viewing angles within a short amount of time, and the images thus generated may be used to calculate a depth map.

While the present invention has been described in connection with what are considered the most practical embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method of using a light-field camera to generate a full depth-of-field image, the light-field camera including a main lens for collecting light field information from a scene, a micro-lens array that includes a plurality of microlenses, a light sensing component, and an image processing unit, said method comprising:
(a) forming, using the micro-lens array, a plurality of micro-images at different positions of the light sensing component according to the light field information collected by the main lens, each of the micro-images including a plurality of pixels;
(b) for each of the micro-images, obtaining, by the image processing unit, an image pixel value according to one of the pixels that is disposed at a specific position of the micro-image, wherein the specific positions of the micro-images correspond to each other; and
(c) arranging, by the image processing unit, the image pixel values obtained for the micro-images according to positions of the micro-images on the light sensing component to generate the full depth-of-field image.

2. The method as claimed in claim 1, wherein, in step (b), the image processing unit obtains a pixel value of said one of the pixels that is disposed at the specific position of the micro-image to serve as the image pixel value of the micro-image.

3. The method as claimed in claim 1, wherein, in step (b), the image processing unit obtains a weighted average of pixel values of said one of the pixels that is disposed at the specific position of the micro-image, and pixels disposed in a vicinity of said one of the pixels, the weighted average serving as the image pixel value of the micro-image.

4. The method as claimed in claim 1, wherein, in step (b), the specific position corresponds to a specific viewing angle.

5. The method as claimed in claim 1, wherein, in step (b), the specific position of the micro-image is a position at or adjacent to a center of the micro-image.

6. The method as claimed in claim 1, further comprising:
(d) after step (c), performing, by the image processing unit, interpolation on the full depth-of-field image generated in step (c) to increase resolution of the full depth-of-field image.

7. The method as claimed in claim 6, further comprising:
(e) sharpening, by the image processing unit, the full depth-of-field image whose resolution was increased in step (d).

8. A light-field camera comprising:
a main lens, a micro-lens array including a plurality of microlenses, and a light sensing component arranged in order from an object side to an image side,
said main lens to collect light field information from a scene,
said micro-lens array to form a plurality of micro-images at different positions of said light sensing component according to the light field information collected by said main lens, each of the micro-images including a plurality of pixels; and
an image processing unit configured to:
for each of the micro-images, obtain an image pixel value according to one of the pixels that is disposed at a specific position of the micro-image, wherein the specific positions of the micro-images correspond to each other; and
arrange the image pixel values obtained for the micro-images according to positions of the micro-images on the light sensing component to generate the full depth-of-field image.

9. The light-field camera as claimed in claim 8, wherein, for each of the micro-images, said image processing unit obtains a pixel value of said one of the pixels that is disposed at the specific position of the micro-image to serve as the image pixel value of the micro-image.

10. The light-field camera as claimed in claim 8, wherein, for each of the micro-images, said image processing unit obtains a weighted average of pixel values of said one of the pixels that is disposed at the specific position of the micro-image, and pixels disposed in a vicinity of said one of the pixels, the weighted average serving as the image pixel value of the micro-image.

11. The light-field camera as claimed in claim 8, wherein the specific position corresponds to a specific viewing angle.

12. The light-field camera as claimed in claim 8, wherein the specific position of the micro-image is a position at or adjacent to a center of the micro-image.

13. The light-field camera as claimed in claim 8, wherein said image processing unit is further configured to perform interpolation on the full depth-of-field image to increase resolution of the full depth-of-field image.

14. The light-field camera as claimed in claim 13, wherein said image processing unit is further configured to sharpen the full depth-of-field image whose resolution was increased thereby.
